(19) United States
(12) Patent Application Publication
(10) Pub. No.: US 2011/0103038 A1
(43) Pub. Date: May 5, 2011

(54) WHITE LED DEVICE

(75) Inventor: Wen-Joe Song, Taipei (TW)

(73) Assignee: KINGBRIGHT ELECTRONICS CO., LTD., Chung-Ho (TW)

(21) Appl. No.: 12/754,676

(22) Filed: Apr. 6, 2010

(30) Foreign Application Priority Data
Oct. 30, 2009 (TW) 098136870

(51) Int. Cl. F21V 9/16; H01L 33/00

(52) U.S. Cl. 362/84; 257/89; 257/E33.059

(57) ABSTRACT

An improved white LED device comprises at least one first LED component, at least one second LED component, and at least one translucent member. The first LED component emits a blue light having a peak wavelength of 440-470 nm; the second LED component emits a red light having the peak wavelength of 600-630 nm; and the translucent member contains at least one fluorescent substance scattered throughout the translucent member. The fluorescent substance is able to absorb some of the blue light, and emits yellow green light having the peak wavelength of 500-570 nm, wherein when the blue light and yellow green light are mixed, the CIE 1931 chromaticity diagram is represented by a polygon with color coordinates (0.20,0.50), (0.20,0.30), (0.29,0.30), and (0.40,0.50), furthermore, after mixing the red light, the blue light, and the yellow green light, the improved white LED device emits a white light with high color rendering, and a color temperature of the white light ranges between 2500-7000 K.

### CROSS-REFERENCE TO RELATED APPLICATION

This application claims foreign priority from a Taiwan Patent Application, Ser. No. 098136870, filed on Oct. 30, 2009.

### BACKGROUND OF THE INVENTION

1. Technical Field

The present invention relates to a white LED device, and more particularly, to an improved white LED device which is composed of a blue LED component, a red LED component, and a fluorescent substance for absorbing blue light, such that the improved white LED device emits white light with high color rendering.

2. Description of Related Art

The color rendering is defined as an index for light to representing a color development ability on an object. The quality of the color rendering of the light is usually determined by color comparison of the appearance of the object according to a reference light (standard light) at the same color temperature, wherein the reference light usually means day-light or black body radiation. High color rendering light has a better performance in the aspect of vivid colors on an object, so that the color perception of the object to human eyes is closer to the effect of natural light under the illumination of the high color rendering light. However, the spectrum of the light will determine light colors thereof. One light color can be the composition of two or more monochromatic lights. Thus, two lights with the same light color may be composed of various lights with different emission spectrums, so that the light with broader emission spectrum is more likely to represent better quality of color rendering.

Light sources for general lighting, for example, mega stores and houses, usually require higher color rendering. According to the standard of the Energy Star of U.S.A., the color rendering index (CRI) for general illumination shall be greater than 75. The light emitted from mercury lamps and high-pressure sodium lamps usually show relatively lower color rendering index (CRI), which is about 20. Thus, the color of objects under the illumination of the mercury lamp or the high-pressure sodium lamp would impart an unnatural feeling to human eyes. Therefore, to use the mercury lamp and/or the high-pressure sodium lamp for general illumination for a long period of time that will create a burden for human eyes. The mercury lamps and/or the high-pressure sodium lamps are usually used as indicator lamps. Since LEDs have relatively longer life time, white LEDs have been widely applied as light sources. A conventional white LED is composed of a blue LED component and a yellow fluorescent substance. The blue light of the blue LED component generates a peak wavelength of around 460 nm, and the yellow fluorescent substance is able to absorb part of the blue light and then converts the blue light into yellow-green light, which has a peak wavelength of about 560 nm. Referring to FIG. 1, an emission spectrum of a conventional white LED is shown. The emission spectrum of the conventional white LED is the combination of the emission spectrum emitted by the blue LED component having the peak wavelength of 460 nm and the emission spectrum emitted by the yellow fluorescent substance having the peak wavelength of 560 nm. In FIG. 1, the conventional white LED emits visible light wavelength in the range of 425-750 nm, and its color rendering index (CRI) is about 60-70, which belongs to the moderate color rendering level.

However, as shown in FIG. 1, the wavelength in the emission spectrum of the conventional white LED exceeds 600 nm, the spectral intensity obviously starts to decay. This indicates that the color rendering of the conventional white LED is inadequate in a red light range. Thus, when using the white light emitted from the conventional white LED to illuminate objects, the emission spectrum of reflected light will attenuate when falling in the red light range, thus resulting in poor color rendering. In order to correct the above shortcomings, nowadays, the blue LED component has been used in combination with a variety of fluorescent substances with different colors, so that the combination of multiple lights with different wavelengths is able to improve the color rendering of the white LED. Although this approach of using multiple lights with different wavelengths could effectively improve the color rendering of the white LED The application of various fluorescent substances for improving the color rendering has two major shortcomings:
1. The excitation rate of the fluorescent substance with the longer wavelength is not satisfactory; and
2. When the fluorescent substance is being excited, some energy may be lost in the process of wavelength conversion from a shorter wavelength to a longer wavelength.

Owing to the shortcomings mentioned above, the white LED device with the combination of a blue LED component and a multi-color fluorescent substance has produced a lower overall efficiency in the electro-optical conversion. In view of the shortcomings of the conventional white LED, an improved white LED device according to the present invention is proposed.

### SUMMARY OF THE INVENTION

The primary objective of the present invention is to provide an improved white LED device, in which by mixing blue light emitted from a first LED component, red light emitted from a second LED component, and yellow-green light emitted from a fluorescent substance, white light with high color rendering is then produced.

In order to achieve the above objectives, an improved white LED device is provided, which comprises at least one first LED component, at least one second LED component, and a translucent member. The first LED device emits blue light with a peak wavelength of 440-470 nm; the second LED device emits red light with a peak wavelength of 600-630 nm; and the translucent member used to enwrap the first and second LED components contains at least one fluorescent substance, the fluorescent substance is able to absorb part of the blue light and emit yellow-green light with a peak wavelength of 500-570 nm. After mixing the blue light and the yellow-green light, the CIE 1931 chromaticity diagram represents a polygon with color coordinates (0.20, 0.50), (0.20, 0.30), (0.29, 0.30), and (0.40, 0.50). Furthermore, by way of mixing the red light, the blue light and the yellow-green light, the improved white LED device emits white light with high color rendering, a color temperature range of the white light is in 2500-7000 K.

### BRIEF DESCRIPTION OF THE SEVERAL VIEWS OF THE DRAWINGS

FIG. 1 is a light spectrum emitted from a conventional white LED.

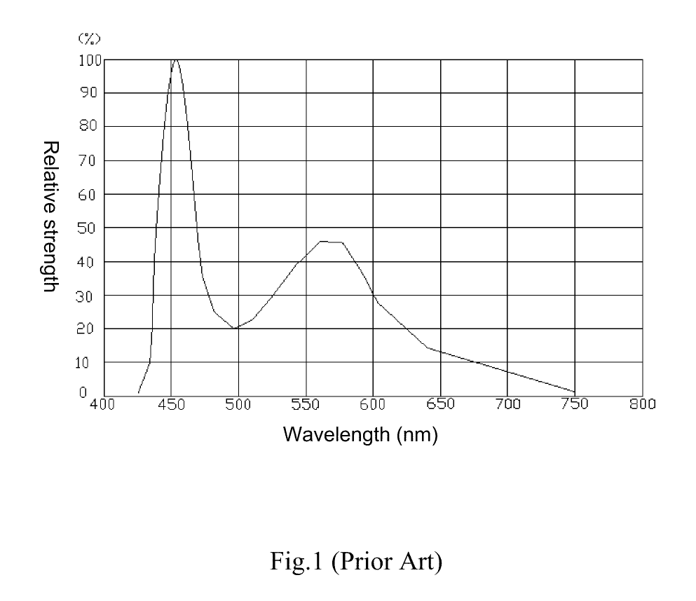

FIG. 2 is a front view of an improved white LED device according to a first embodiment of the present invention.

FIG. 3 is a CIE 1931 chromaticity diagram.

FIG. 4 is an emission spectrum of a white light emitted from the improved white LED device.

FIG. 5 is a bar chart representation of a color rendering index of the improved white LED device.

FIG. 6 is the front view of the improved white LED device according to a second embodiment of the present invention.

FIG. 7 is a perspective view of the improved white LED device according to a third embodiment of the present invention.

### DETAILED DESCRIPTION OF THE INVENTION

To describe an improved white LED device of the present invention more clearly, detailed description will be made below with reference to the attached drawings.

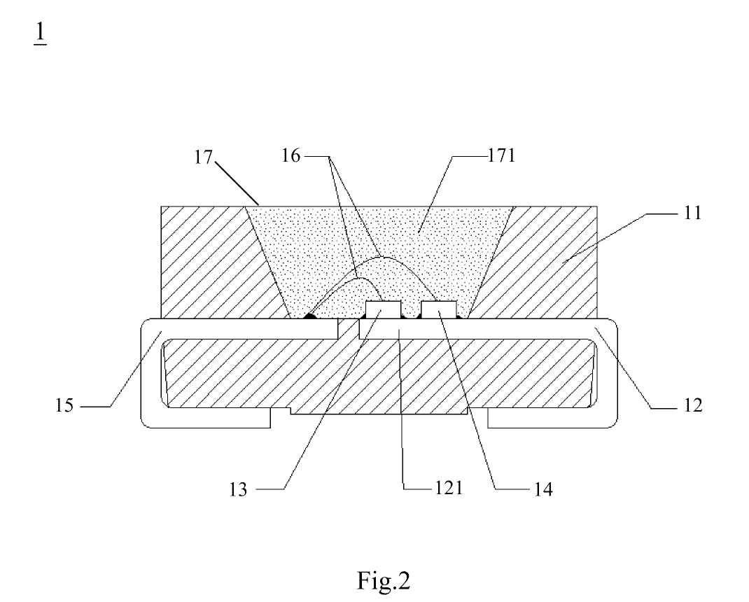

Referring to FIG. 2, which illustrates a front view of the improved white LED device according to a first embodiment of the present invention, the improved white LED device 1 includes:

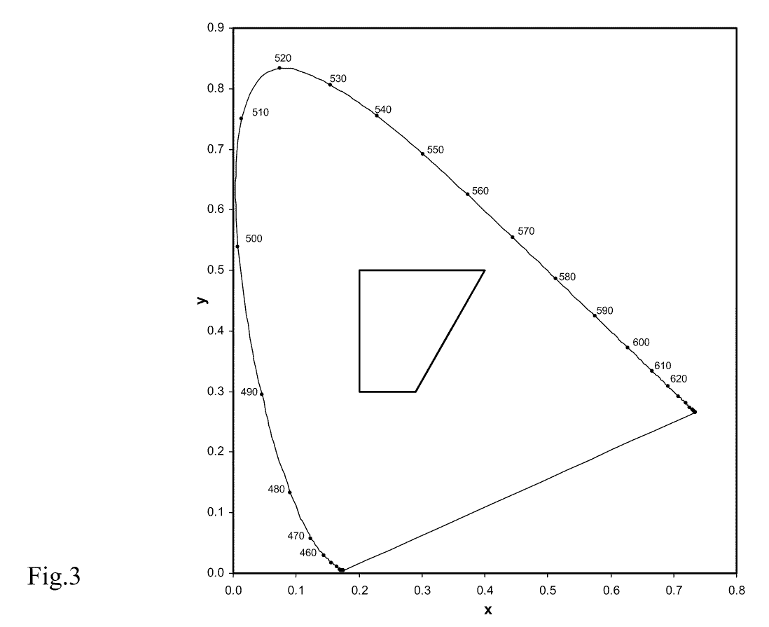

a first LED component 13, which emits blue light with a peak wavelength of 440-470 nm; a second LED component 14, which emits red light with a peak wavelength of 600-630 nm; a translucent member 17, which enwraps the first LED component 13 and the second LED component 14, the translucent member 17 contains a fluorescent substance 171, wherein an absorption spectrum of the fluorescent substance 171 corresponds with an emission spectrum of the blue light emitted by the first LED component 13, so that the fluorescent substance 171 is able to absorb part of the blue light, and emit a yellow green light with the peak wavelength of 500-570 nm. Referring to FIG. 3, which illustrates a CIE 1931 chromaticity diagram, the CIE 1931 chromaticity diagram shows a polygon with color coordinates (0.20,0.50), (0.20,0.30), (0.29,0.30), and (0.40,0.50) after mixing the blue light and the yellow-green light, furthermore, by way of mixing the red light, the blue light, and the yellow-green light, the improved white LED device 1 emits a white light with high color rendering, and a color temperature of the white light ranges in 2500-7000 K.

Continuously referring to FIG. 2, according to the first embodiment of the present invention, the improved white LED device 1 further includes: a first electrode 12, which is connected to the first LED component 13 and the second LED component 14, such that the first LED component 13 and the second LED component 14 are electrically connected to an external electrical device; and a second electrode 15, which is electrically connected to the first LED component 13 and the second LED component 14 through a plurality of metal wires 16 in order to connect the first LED components 13 and the second LED components 14 to the external electrical device. Moreover, in the first embodiment of the present invention, a shell 11 is used to enclose the first electrode 12, the first LED component 13, the second LED component 14, the plurality of metal wires 16, the second electrode 15, and the translucent member 17 so as to form the improved white LED device 1 as a surface-mount device (SMD).

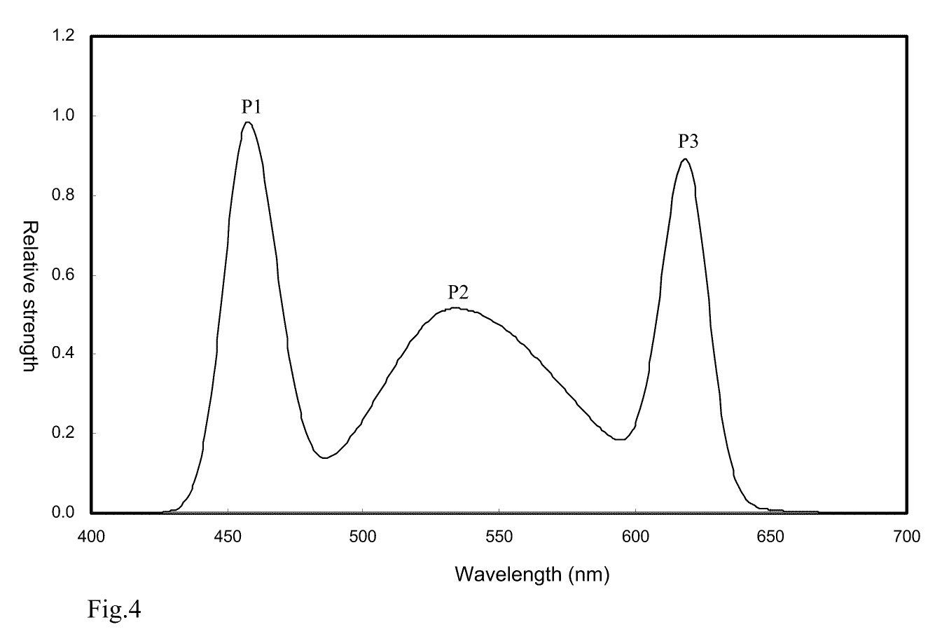

Referring to FIG. 4, which illustrates the emission spectrum of the white light emitted from the improved white LED device according to the first embodiment of the present invention, wherein the peak wavelength range of the blue light is 440-470 nm, and the peak wavelength range of the yellow-green light is 500-570 nm, and the peak wavelength range of the red light is 600-630 nm. As shown in FIG. 4, the first LED component 13 employed in the first embodiment emits the blue light, which has a peak wavelength P1 in the vicinity of 455 nm; the fluorescent substance 171 absorbs the blue light and then emits the yellow-green light, which has a peak wavelength P2 in the vicinity of 545 nm; and the second LED component 14 emits the red light, which has a peak wavelength P3 in the vicinity of 625 nm. As shown in FIG. 4, after mixing the blue light with the peak wavelength of 455 nm, the yellow-green light with the peak wavelength of 540 nm, and the red light with the peak wavelength of 615 nm, the white light has high color rendering, and the emission spectrum of the white light almost covers the entire visible light wavelength range (wavelength of visible light lies in the range of 400-700 nm), so that the improved white LED device 1 has a fairly wide spectral range of the red light, in other words, the improved white LED device 1 possess a good repeatability of the red light, and a high color rendering index (CRI).

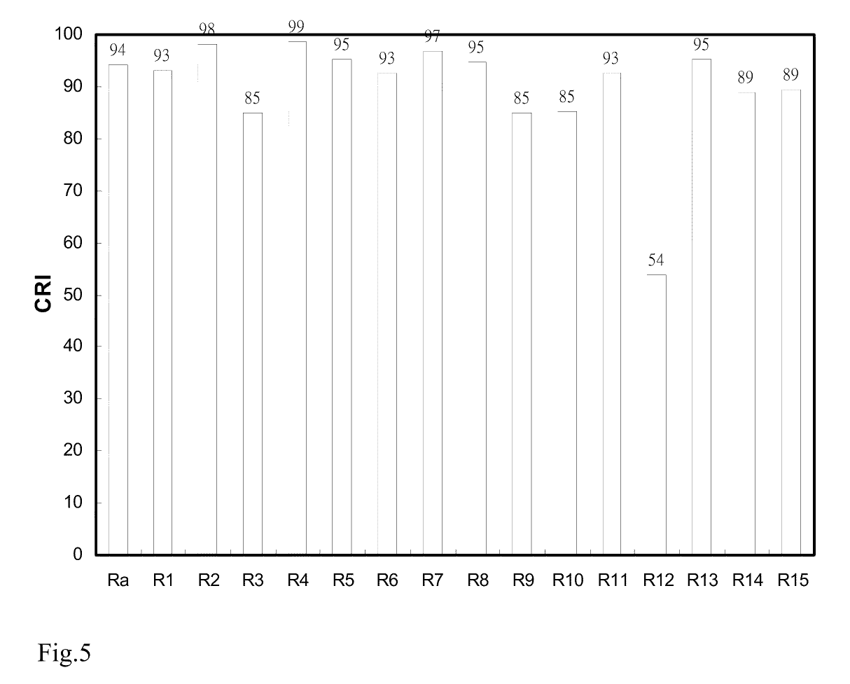

However, the method to determine the color rendering index (CRI) of a light is to use a reference light (Standard light) and the light illuminating on each of eight test colors marked in Munsell color system respectively, and then to compare with the color rendering index of the eight test colors, and quantify their differences respectively, so that the color rendering against all colors of the light is obtained. Referring to FIG. 5, that is a bar chart of the color rendering index of the improved white LED device 1, wherein the columns labeled R1 to R8 on the horizontal axis represent the high color rendering of the white light emitted from the white LED device 1 against the eight test colors under illumination at a color temperature of 6000 K. As shown in FIG. 5, by averaging the values of R1 to R8, an average color rendering index (Ra) is 94, which is a great color rendering value. Therefore, the improved white LED device 1 is able to emit the white light with high color rendering, and suit to be used for general illumination. Besides, bars labeled R9 to R15 on the horizontal axis represent the color rendering index of the white light with high color rendering against other test colors specified by Munsell color system, and the test results provide an understanding of the color rendering ability of the white light in other colors, but the values of R9 to R15 are not included while calculating the average color rendering index (Ra).

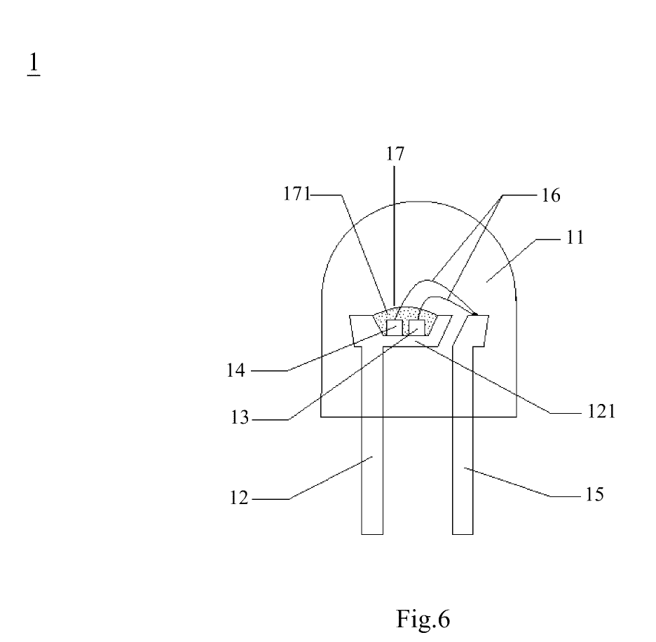

In order to increase practical applications for the improved white LED device 1, please refer to FIG. 6, which illustrates a front view of a second embodiment of the present invention. The main components of the second embodiment is almost the same as the main components of the first embodiment and is made for a dual in-line package (DIP) type.

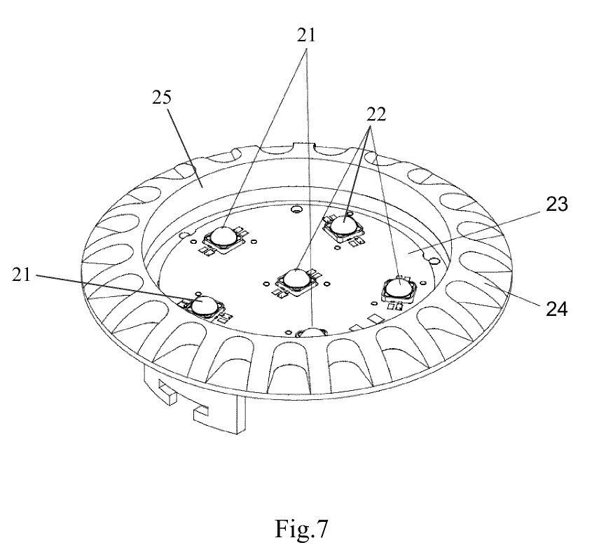

However, the present invention is to use the first LED component 13 for emitting the blue light, and the second LED component 14 for emitting the red light, as well as the fluorescent substance 171 for absorbing the blue light and emitting the yellow-green light, furthermore, after mixing the blue light, the red light, and the yellow-green light, the white LED device 1 develops the white light with high color rendering. The device structure of the present invention is not limited to the types of the surface-mount device (SMD) and the dual in-line package (DIP). Sequentially, referring to FIG. 7, which illustrates a perspective diagram of a third embodiment of the present invention. As shown in FIG. 7, a first shell encloses the first electrode 12, the first LED component 13, the plurality of metal wires 16, the second electrode 15, and the translucent member 17 to form a first LED device 21; and a second shell encloses the first electrode 12, the second LED component 14, the plurality of metal wires 16, the second electrode 15, and the translucent member 17 to form a second LED device 22. However, according to the cost control, the translucent member 17 enclosed by the second shell does not require doping the fluorescent substance 171 that is used to absorb the blue light. Thereafter, a number of the first LED devices 21 and the second LED devices 22 are mounted on a printed circuit board 23, and the first LED devices 21, the second LED devices 22 and the printed circuit board 23 are accommodated by a large shell 24. A lamp shade 25 covers on the large shell 24 to form the architecture of the third embodiment of the invention. In the third embodiment, the first LED component 13 and the second LED component 14 are separately installed in different shells, and through an external nixing device, these LED devices may emit white light with high color rendering. Thus, the third embodiment is different from the first embodiment of the surface-mount device (SMD) type, or the second embodiment of the dual in-line package (DIP) type. Hence, the third embodiment of the present invention may be treated as an independent white LED device.

The above description of various embodiments of the invention has already provided full disclosure of the present invention, in summary, the present invention possesses the following advantages:
1. By mixing the blue light emitted from the first LED component, the red light emitted from the second LED component, and the yellow-green light emitted from the fluorescent substance, the LED device is able to produce the white light with high color rendering, and the emission spectrum of the white light is able to cover the entire range of visible light wavelengths, and has the repeatability for the red light range. Moreover, the emission of the high color rendering white light has the average color rendering index (Ra) of 91, and the illumination quality of the white light comes fairly close to day-light, so that the present invention is ideal for general illumination.
2. According to the present invention, the white LED device can be assembled as either the surface-mount device (SMD) or the dual in-line package (DIP), so as to provide the needed flexibility and practicality for different applications.

What is claimed is:

1. An improved white LED device comprising:
at least one first LED component, emitting a blue light having a peak wavelength ranging between 440-470 nm;
at least one second LED component, emitting a red light with the peak wavelength ranging between 600 and 630 nm, and
at least one translucent member, containing at least one fluorescent substance scattered throughout the translucent member, wherein an absorption spectrum of the fluorescent substance is consistent with the emission spectrum of the blue light from the first LED component, so that the fluorescent substance is able to absorb some of the blue light, and emitting a yellow green light with the peak wavelength ranging between 500 and 570 nm, and a CIE 1931 chromaticity diagram of mixing the blue light and the yellow green light representing a polygon with color coordinates (0.20, 0.50), (0.20, 0.30), (0.29, 0.30), and (0.40, 0.50), furthermore, blending the red light, the blue light, and the yellow green light, the improved white LED device emitting a white light with high color rendering, a color temperature of the white light ranging between 2500 and 7000 K.

2. The improved white LED device according to claim 1, further comprising:
at least one first electrode, connecting to the first LED component and the second LED component, and electrically connecting the first and second LED components to an external electrical device;
a plurality of metal wires, electrically coupling to the first LED component and the second LED component; and
at least one second electrode, electrically connecting to the first LED component and the second LED component via a plurality of metal wires, and electrically coupling the first LED component and the second LED component to the external electrical device.

3. The improved white LED device according to claim 2, wherein the first electrode, the first LED component, the second LED component, the plurality of metal wires, the second electrode, and the light translucent member are all enclosed in a shell.

4. The improved white LED device according to claim 2, wherein the first electrode, the first LED component, the plurality of metal wires, the second electrode, and the translucent member are all enclosed in a first shell, while the first electrode, the second LED component, the plurality of metal wires, the second electrode, and the translucent member are all enclosed in a second shell.

5. An improved white LED device, comprising:
a shell;
at least one first electrode, one end of the first electrode being covered by the shell and forming an installation site, and an opposite end of the first electrode extending outside the shell and connecting to an external electrical device;
at least one first LED component, being disposed on the installation site, the first LED component emitting a blue light;
at least one second LED component, being disposed on the installation site, the second LED component emitting a red light;
at least one second electrode, one end of the second electrode being covered by the shell, and an opposite end of the second electrode extending outside the shell and connecting to the external electrical device;
a plurality of metal wires, electrically coupling the first LED component and second LED component to the second electrode; and
a translucent member, being set on the installation site and enclosing the first LED component, the second LED component, and the plurality of metal wires, wherein the translucent member containing a fluorescent substance, which scattering within the translucent member, moreover, an absorption spectrum of the fluorescent substance cohering with an emission spectrum of the blue light emitted from the first LED component, so that the fluorescent substance is able to soak part of the blue light, and emitting a yellow green light, furthermore, the improved white LED device emitting a white light with high color rendering after mixing the blue light, the red light, and the yellow green light.

6. The improved white LED device according to claim 5, wherein the electrical device is a printed circuit board.

7. The improved white LED device according to claim 5, wherein the emission spectrum of the blue light has a peak wavelength ranging between 440 and 470 nm; the emission spectrum of the yellow green light having the peak wavelength ranging between 500 and 570 nm; and the emission spectrum of the red light having the peak wavelength ranging between 600 and 630 nm.
